(19) United States
(12) Patent Application Publication
(10) Pub. No.: US 2015/0152004 A1
(43) Pub. Date: Jun. 4, 2015

(54) GLASS SHEET/FLUORORESIN LAMINATE

(71) Applicant: Asahi Glass Company, Limited, Tokyo (JP)

(72) Inventors: Masahiro ITO, Tokyo (JP); Hiromasa YAMAMOTO, Tokyo (JP); Satoshi SHIRATORI, Tokyo (JP); Tetsuya KOYAMA, Tokyo (JP); Norihide SUGIYAMA, Tokyo (JP); Koji KOGANEZAWA, Tokyo (JP); Ryota NAKAJIMA, Tokyo (JP)

(21) Appl. No.: 14/614,987

(22) Filed: Feb. 5, 2015

Related U.S. Application Data
(63) Continuation of application No. PCT/JP2013/071401, filed on Aug. 7, 2013.

(30) Foreign Application Priority Data
Aug. 9, 2012 (JP) 2012-176972
Oct. 22, 2012 (JP) 2012-233197
Apr. 2, 2013 (JP) 2013-077237

(51) Int. Cl. C03C 17/32; H01L 51/52; H01L 51/44

(52) U.S. Cl. CPC C03C 17/32; H01L 51/448; H01L 51/5253

(57) ABSTRACT

To provide a laminate which is thin and light in weight, which has excellent gas barrier properties, flexibility and durability, and which is excellent in the flatness. A glass sheet/fluororesin laminate comprising a glass sheet having a thickness of from 10 to 500 μm, and a fluororesin coated layer preferably having a thickness of from 0.1 to 1,000 μm. Particularly, the thickness ratio of the fluororesin coated layer to the glass sheet is preferably from 0.001 to 10 by the fluororesin coated layer/the glass sheet. Further, the transmittance at a wavelength of from 400 to 700 nm is preferably at least 80%. Further, this laminate is suitable as a protective plate. Still further, this laminate is suitably applied to a photoelectric conversion element.

### CROSS REFERENCE TO RELATED APPLICATIONS

This application is a continuation application filed under 35 U.S.C. 111(a) claiming benefit under 35 U.S.C. §§120 and 365(c) of PCT International Application No. PCT/JP2013/071401 filed on Aug. 7, 2013, which is based upon and claims the benefit of priority to Japanese Patent Application No. 2012-176972 filed on Aug. 9, 2012, Japanese Patent Application No. 2012-233197 filed on Oct. 22, 2012 and Japanese Patent Application No. 2013-077237 filed on Apr. 2, 2013 the contents of which are hereby incorporated by reference in their entireties.

### TECHNICAL FIELD

The present invention relates to a glass sheet/fluororesin laminate.

### BACKGROUND ART

For the surface of a display member of e.g. a liquid crystal display or a mobile terminal, a cover glass is used for protection. Further, for the surface of a photoelectric conversion element such as a solar cell or an LED also, a cover glass is used for protection. These are applications utilizing excellent durability, transparency, etc. of glass.

In recent years, remarkable weight saving is required for a display member and a photoelectric conversion element. Accordingly, a technique to make glass thin is developed. However, there is a problem such that if glass is made thin, it is easily broken. Accordingly, a technique to achieve objects such as weight saving, shock resistance, durability, gas barrier properties and flexibility by a composite with a resin material has been proposed (Patent Documents 1 to 4).

### PRIOR ART DOCUMENTS

### Patent Documents

Patent Document 1: JP-A-2010-42588
Patent Document 2: JP-A-2011-16708
Patent Document 3: JP-A-2011-51278
Patent Document 4: WO2008/149793

### DISCLOSURE OF INVENTION

### Technical Problem

In technique as disclosed in Patent Documents 1 to 3, long term durability and light resistance are insufficient since a hydrocarbon resin is used as the resin, and discoloration or deterioration of the resin occurs in some cases. Further, in technique as disclosed in Patent Document 4, the problem of deterioration of the resin is overcome by use of a fluororesin. However, in this technique, a fluororesin film is laminated by thermal compression bonding. In this case, the laminate may not be flat. Specifically, it is possible to reduce the deviation in the thickness of the laminate, however, it is difficult to secure the self-supporting flatness of the entire laminate. For example, in a case where the laminate is placed on a plane, so-called “undulations” are observed such that the laminate floats up from the plane in spots.

Under these circumstances, the object of the present invention is to provide a laminate which is thin and light in weight, which is excellent in the gas barrier properties, flexibility and durability, and which is excellent in the flatness.

### Solution to Problem

To achieve the above object, the present invention provides the following.

[1] A glass sheet/fluororesin laminate comprising a glass sheet having a thickness of from 10 to 500 μm, and a fluororesin coated layer.
[2] The glass sheet/fluororesin laminate according to [1], wherein the thickness of the fluororesin coated layer is from 0.1 to 1,000 μm.
[3] The glass sheet/fluororesin laminate according to [1] or [2], wherein the thickness of the fluororesin coated layer is from 0.001 to 10 assuming that the thickness of the glass sheet is 1.
[4] The glass sheet/fluororesin laminate according to any one of [1] to [3], wherein the transmittance at a wavelength of from 400 to 700 nm is at least 80%.
[5] The glass sheet/fluororesin laminate according to any one of [1] to [4], wherein the fluororesin is a solvent-soluble fluororesin.
[6] The glass sheet/fluororesin laminate according to [5], wherein the solvent-soluble fluororesin is a fluororesin having a cyclic structure in its main chain.
[7] The glass sheet/fluororesin laminate according to [5], wherein the solvent-soluble fluororesin is polyvinylidene fluoride.
[8] The glass sheet/fluororesin laminate according to any one of [1] to [4], wherein the fluororesin is a cured fluororesin obtained by curing a solvent-soluble curable fluororesin.
[9] A method for producing a glass sheet/fluororesin laminate, which comprises applying a solution of a fluororesin to at least one side of a glass sheet having a thickness of from 10 to 500 μm, and then removing the solvent to form a fluororesin coated layer.
[10] The method for producing a glass sheet/fluororesin laminate according to [9], wherein the solution of a fluororesin is a solution of a curable fluororesin, and after the solvent is removed, the curable fluororesin is cured to form a coated layer of a cured fluororesin.
[11] A protective plate comprising the glass sheet/fluororesin laminate as defined in any one of [1] to [8].
[12] A photoelectric conversion element, having the glass sheet/fluororesin laminate as defined in any one of [1] to [8].
[13] A semiconductor device having as a substrate the glass sheet/fluororesin laminate as defined in any one of [1] to [8].

### Advantageous Effects of Invention

The glass sheet/fluororesin laminate of the present invention is thin and light in weight, has excellent gas barrier properties, flexibility and durability, and is excellent in the flatness. Further, the protective plate of the present invention is excellent in applicability to various uses, and is excellent in the protecting performance and the durability. Further, the yield of the photoelectric conversion element of the present invention at the time of production is high, and the element is excellent in the durability.

### DESCRIPTION OF EMBODIMENTS

### Glass Sheet/Fluororesin Laminate

The glass sheet/fluororesin laminate of the present invention comprises a glass sheet having a thickness of from 10 to 500 μm and a fluororesin coated layer. Hereinafter in this specification, the glass sheet/fluororesin laminate will sometimes be referred to simply as “laminate”. Further, in this specification, “a film” means a free standing film of a resin formed in the form of a sheet.

### (Glass Sheet)

The glass sheet to be used for the laminate of the present invention (hereinafter sometimes referred to simply as “glass sheet”) has a thickness of from 10 to 500 μm. If the glass sheet has a thickness less than 10 μm, when it is formed into a laminate, the laminate tends to have insufficient shock resistance and is likely to be broken in some cases. Further, if it has a thickness exceeding 500 μm, the flexibility of the resulting laminate is insufficient in some cases. The thickness is more preferably from 20 to 300 μm, particularly preferably from 30 to 100 μm.

The surface of the glass sheet used in the present invention is preferably flat. Particularly, the surface roughness is preferably at most 30 nm, more preferably at most 1 nm by the arithmetic mean roughness (Ra) as defined by JIS B0601. When the surface is flat, the light transmittance tends to be high, and even when an electrode such as a transparent electrically conductive film is laminated on the glass surface, the film resistance tends to be uniform, and defects are unlikely to occur.

The thickness of the glass sheet is preferably uniform. Specifically, the deviation in thickness is preferably at most 15% (for example, the deviation is at most 15 μm relative to a thickness of 100 μm) by the PV (peak to valley) value. When the thickness is uniform, the glass sheet tends to have a favorable outer appearance.

The light transmittance of the glass sheet is preferably at least 90% within a wavelength range of from 400 to 700 nm.

Further, the dielectric constant of the glass sheet is preferably from 5 to 7 at 10 kHz. Further, the Young's modulus of the glass sheet is preferably from 70 to 95 GPa, more preferably from 75 to 90 GPa.

Still further, the coefficient of linear expansion of the glass sheet is preferably from 3×10⁻⁶ to 5×10⁻⁶/° C. (from 3 to 5 ppm/° C.) at from 0 to 200° C. When the glass sheet has such properties, the laminate is excellent as a protective plate of e.g. a photoelectric conversion element or a display member, a substrate of a semiconductor device, etc.

The material and the composition of the glass sheet are not particularly limited. For example, soda lime glass, alkaliborosilicate glass, alkali-free borosilicate glass or alkali-free aluminosilicate glass may, for example, be mentioned. Among them, in view of high durability, high elastic modulus and low coefficient of thermal expansion, preferred is alkali-free borosilicate glass or alkali-free aluminosilicate glass. In the following, alkali-free borosilicate glass and alkali-free aluminosilicate glass will sometimes be referred to generally as “alkali-free glass”. By using alkali-free glass, in formation of a semiconductor device on the glass, deficiency of the device due to alkali will not occur. Alkali-free glass means glass having a glass composition as represented by oxides having a content of alkali metal oxides less than 1 mol % (including 0 mol %).

Further, the glass sheet may be one having tempering treatment applied thereto. The tempering treatment is preferably chemical tempering. By chemical tempering, even a thin glass sheet may effectively be tempered. In such a case, such an effect is obtained that the laminate is hardly broken even though it is thin and light in weight.

### (Fluororesin)

The fluororesin in the present invention means a fluororesin selected from the group consisting of a cured product of a solvent-soluble curable fluororesin, a solvent-soluble fluororesin and a mixture thereof. Further, “a solution of a solvent-soluble curable fluororesin” and “a solution of a solvent-soluble fluororesin” will sometimes be referred to generally as “a fluororesin solution”. Further, the term “solvent-soluble” is not limited to a case where the fluororesin can be formed into a solution in a strict sense but includes a case where a state such that the fluororesin is stably dispersed is maintained. Further, a solution state which is somewhat turbid may be included. The fluororesin solution is preferably one subjected to filtration. Particularly, one subjected to filtration using filter paper with a nominal aperture of at most 5 μm is preferred, whereby foreign matters are removed and a smooth laminate will be obtained.

Further, the fluorine content of the fluororesin is preferably at least 5 mass %, more preferably at least 10 mass %. If the fluorine content is high, the water absorption and the relative dielectric constant of the resin tend to be low, and the reliability and the durability when an element is formed tend to be high. The upper limit of the fluorine content is preferably at most 76 mass %, whereby the fluororesin is easily formed into a solution, and is more preferably at most 70 mass %. Here, the fluorine content is a proportion of the molecular weight occupied by fluorine atoms and is usually calculated based on the chemical formula of the monomer. When a plurality of monomers are used as mixed, the fluorine content is calculated from their mixture ratio (mass ratio).

The fluororesin (polymer) may, for example, be specifically a polymer of a fluorinated olefin or a cyclic polymer of a fluorinated diene compound. The fluorinated olefin may, for example, be vinyl fluoride, vinylidene fluoride, trifluoroethylene, chlorotrifluoroethylene, tetrafluoroethylene, hexafluoropropylene, a fluoroalkyl(meth)acrylate, a fluoroalkyl vinyl ether or a perfluoro(alkyldioxole). The fluorinated diene compound which may undergo cyclopolymerization may, for example, be perfluoro(aryl vinyl ether) or perfluoro(butenyl vinyl ether).

Such a polymer may be a homopolymer of the above monomer (such as a fluorinated olefin) or may be a copolymer. In the case of a copolymer, it may be a copolymer of the above fluorinated olefin and a monomer containing no fluorine atom. The monomer containing no fluorine atom may, for example, be an olefin, a vinyl ether such as an alkyl vinyl ether, a vinyl ester such as an alkyl vinyl ester or a (meth)acrylate such as an alkyl(meth)acrylate. Further, the monomer containing no fluorine atom may be a compound having a reactive group such as a hydroxy group.

Such a fluororesin and a cured product thereof are excellent in broad aspects of the durability, the weather resistance, the water repellency, the antifouling property, the transparency, etc.

Further, “(meth)acrylate” means both acrylate and methacrylate.

The solvent-soluble fluororesin may, for example, be a homopolymer or copolymer of vinylidene fluoride, a homopolymer of copolymer of a cyclic fluorinated monomer (a monomer in which a carbon atom in a polymerizable unsaturated group is a carbon atom constituting the ring) such as a perfluoro(alkyldioxole), a homopolymer or copolymer of a fluorinated diene compound which may undergo cyclopolymerization, a copolymer of tetrafluoroethylene and vinyl alcohol, or a copolymer of a fluoroalkyl(meth)acrylate and a (meth)acrylate containing no fluorine atom. Further, the homopolymer or copolymer of the cyclic fluorinated monomer and the homopolymer or copolymer of the fluorinated diene compound which may undergo cyclopolymerization are polymers having a cyclic structure in their main chains (polymers in which some of carbon atoms in the main chain are carbon atoms constituting the ring).

The solvent-soluble fluororesin is preferably a homopolymer of vinylidene fluoride, a copolymer of perfluoro(dimethyldioxole) and tetrafluoroethylene, a cyclic polymer of perfluoro(butenyl vinyl ether) or a copolymer of tetrafluoroethylene and vinyl alcohol, particularly preferably a homopolymer of vinylidene fluoride or a cyclic polymer of perfluoro(butenyl vinyl ether). Further, the homopolymer of vinylidene fluoride is a polymer which may be crosslinked by heat treatment, but is regarded as a solvent-soluble fluororesin (not a curable fluororesin) in the present invention.

The solvent-soluble curable fluororesin may, for example, be a copolymer of chlorotrifluoroethylene or tetrafluoroethylene and an alkyl vinyl ether having a curable functional group such as a hydroxy group, or a fluorinated arylene ether polymer having polymerizable functional groups such as vinyl groups. Further, the above copolymer of tetrafluoroethylene and vinyl alcohol may be reacted with an alkyl silicate oligomer to obtain a curable fluororesin.

The curable fluororesin having reactive groups may be formed into a cured product by using a compound having a functional group reactive with the reactive groups as a curing agent or a crosslinking agent. For example, a curable fluororesin having hydroxy groups may be formed into a cured product by e.g. a curing agent having an isocyanate group. Further, a fluororesin having polymerizable functional groups such as vinyl groups may be formed into a cured product by e.g. a radical generator.

The solvent-soluble curable fluororesin is preferably a hydroxy group-containing fluororesin comprising a copolymer of chlorotrifluoroethylene and a hydroxy group-containing vinyl ether or the like, a curable fluororesin obtained by reacting a copolymer of tetrafluoroethylene and vinyl alcohol with an alkyl silicate oligomer, or a fluorinated arylene ether polymer having vinyl groups, particularly preferably a fluorinated arylene ether polymer having vinyl groups.

The glass transition temperature of the fluororesin is preferably at most 200° C., more preferably at most 150° C. When the glass transition temperature is low, a stress is less likely to remain in the laminate, and the flatness is hardly impaired due to warpage of the laminate, etc. The transmittance of the fluororesin is preferably at least 80%, more preferably at least 90% within a wavelength range of from 400 to 700 nm.

### (Laminate)

The laminate of the present invention is a laminate of the above glass sheet and a fluororesin coated layer. As the structure of the laminate, typically the following four examples may be mentioned.

(1) A structure comprising a combination of a single layer of the glass sheet and a single layer of the fluororesin coated layer. That is, a structure such that a fluororesin coated layer is formed on one side of the glass sheet.

(2) A structure comprising a combination of a single layer of the glass sheet and two layers of the fluororesin coated layer. That is, a structure such that a fluororesin coated layer is formed on both sides of the glass sheet.

(3) A structure comprising a combination of two layers of the glass sheet and a single layer of the fluororesin coated layer. That is, a structure such that a fluororesin coated layer is sandwiched between two layers of the glass sheet.

(4) A structure comprising a combination of several layers (at least 2 layers) of the glass sheet and several layers (at least 2 layers) of the fluororesin coated layer. That is, a structure such that several layers of the glass sheet and the fluororesin coated layer are alternately formed.

Among such structures, preferred is the structure (1) or (3), whereby the laminate is thin and light in weight, and the flatness of the glass sheet surface can be made use of, and particularly preferred is the structure (1).

Particularly by the structure (1), the sliding property by the fluororesin may be imparted. When the laminate is transported, by disposing the fluororesin coated layer to a side which is likely to be in contact with a transport apparatus, an appropriate sliding property is imparted. As a result, advantages can be obtained such that positioning of the laminate is easily carried out, and a long laminate can be wound with high precision. Further, by the fluororesin coated layer being provided, an appropriate sliding property can be imparted even when the surface of the fluororesin coated layer is smooth. When the fluororesin coated layer is smooth, processing with high precision is possible in processing of the glass sheet surface. Further, by the fluororesin coated layer being provided, an appropriate sliding property can be imparted to the resin layer without using a filler or the like. If a filler is used, falling of the filler may be problematic during operation such as transportation.

By providing the fluororesin coated layer, an electrostatic chuck is likely to be utilized for transportation. That is, if the laminate is to be held by a vacuum chuck, the laminate may be deformed, and an unintended stress may remain. It is possible to transport the laminate by an electrostatic chuck with a relatively low applied voltage.

In the laminate of the present invention, the thickness of the fluororesin coated layer is preferably from 0.1 to 1,000 μm, more preferably from 0.1 to 500 μm, particularly preferably from 1 to 20 μm. Within such a range, it is possible to prevent the glass sheet from being scared or broken, and even when the glass sheet is broken, its flying can be prevented.

In the structure (1), the thickness of the laminate is preferably from 11 to 1,500 μm, more preferably from 30 to 800 μm, particularly preferably from 30 to 110 μm.

The thickness of the laminate of the present invention is preferably uniform. Specifically, the standard deviation of the thickness is preferably at most 50%, more preferably at most 35%. When the thickness is uniform, the laminate tends to have a favorable outer appearance.

In the laminate of the present invention, with respect to the thickness ratio of the fluororesin coated layer to the glass sheet, the thickness of the resin assuming that the thickness of the glass sheet is 1 is preferably from 0.001 to 10, more preferably from 0.01 to 5, particularly preferably from 0.1 to 1. In the case of several layers, their total thickness is considered. Within such a range, the flatness of the laminate tends to be high.

The laminate of the present invention has a transmittance at a wavelength of from 400 to 700 nm of preferably at least 80%, more preferably at least 90%, particularly preferably at least 93%. The laminate is preferably transparent within the above wavelength range, i.e. within a range of visible light. When the laminate is transparent, it may suitably be used as a protective plate to be disposed in front of a display member. Further, when the laminate is used as a substrate of a photoelectric conversion element, the luminous efficiency will not be lowered in a case where the photoelectric conversion element is a light-emitting device, or the power generation efficiency will not be lowered in a case where the photoelectric conversion element is a power generation device.

### <Method for Producing Glass Sheet/Fluororesin Laminate>

The laminate of the present invention comprises a glass sheet and a fluororesin coated layer. The fluororesin coated layer may be formed on the glass sheet by direct coating, or a coating film may be formed by coating on another substrate and then transferred to the glass sheet. Formation by direct coating is preferred, whereby the surface of the fluororesin coated layer tends to be flat.

The method for producing the glass sheet/fluororesin laminate of the present invention comprises applying a solution of a fluororesin to at least one side of a glass sheet having a thickness of from 10 to 500 μm, and then removing the solvent to form a fluororesin coated layer. In a case where the solution of a fluororesin is a solution of a curable fluororesin, after the solvent is removed, the curable fluororesin is cured to form a coated layer of a cured fluororesin.

### (Fluororesin Solution)

The fluororesin solution to be used in the production method of the present invention is not particularly limited so long as coating is possible. The fluororesin solution may be prepared by dissolving a fluororesin in a solvent, or a resin may be synthesized in a solvent.

The fluororesin solution may contain a component other than the fluororesin and the solvent. Particularly, a compound which may react with the fluororesin at the time of formation of the coating film may be contained. For example, a silane such as an alkoxysilane or an alkyl silicate oligomer may be mentioned.

The solid content of the fluororesin solution is preferably from 0.1 to 70 mass %, more preferably from 1 to 15 mass %. Here, the solid content means a proportion of the solid matter obtainable by drying the solution, in the entire solution. For example, it may be measured by putting 1 g of a solution in an aluminum cup, followed by drying in an oven at 100° C. for 10 minutes. The solvent used for the fluororesin solution is not particularly limited so long as the fluororesin is soluble in it. Its boiling point is preferably from 50 to 300° C., more preferably from 100 to 250° C.

### (Application of Fluororesin Solution)

When the fluororesin solution is applied to the glass sheet, the glass sheet may not particularly be treated, or a surface suitability-improving treatment may be applied to the glass sheet. The surface suitability-improving treatment may, for example, be specifically a cleaning treatment or an adhesion-improving treatment. The cleaning treatment may, for example, be water cleaning, steam cleaning, solvent cleaning or UV/ozone cleaning. The adhesion-improving treatment may, for example, be a corona treatment or a primer treatment. The primer to be used in the primer treatment may, for example, be an aminosilane or an epoxysilane.

The method of applying the fluororesin solution is not particularly limited. It may, for example, be specifically spin coating, dip coating, die coating, slit coating, spray coating, ink jet coating, flexographic coating or gravure coating. Application of the fluororesin solution may be conducted once, or may be conducted dividedly in several times.

Then, the solvent is removed from the layer of the fluororesin solution on the glass sheet to obtain a layer of the fluororesin. In a case where the fluororesin is a curable fluororesin, the curable fluororesin is cured substantially simultaneously with removal of the solvent or after removal of the solvent, to form the cured fluororesin. Removal of the solvent is carried out usually by heating the layer of the fluororesin solution to a temperature of at least the boiling point of the solvent to evaporate the solvent. At the time of this heating, a heat-curable fluororesin can be cured substantially simultaneously. The resin may further be heated and cured after removal of the solvent.

In production of the laminate of the present invention, various production methods may be employed depending upon the form of the glass sheet. In a case where the glass sheet is a continuous long sheet, a continuous process is suitable. In the continuous process, after the surface suitability-improving treatment is carried out if necessary, application of the fluororesin solution and heating (removal of the solvent) are carried out continuously, and the obtained laminate is wound into a roll. Particularly in the case of the structure (1) (a structure such that the fluororesin coated layer is formed on one side of the glass sheet), this production method is suitable. Further, in a case where the glass sheet is cut into a certain size and shape, a sheet-fed method is suitable. Particularly in the case of the above structures (2) to (4), this production method is suitable.

### <Protective Plate>

The present invention further provides a protective plate comprising the above laminate. Since the laminate of the present invention is excellent in the transparency and the durability, it is suitable as a protective plate of e.g. a display device. When used as a protective plate, any one of the above structures (1) to (4) may be applicable. In a case where an adhesive fluororesin is employed for the fluororesin coated layer of the laminate, the laminate may be directly bonded to a display device utilizing the fluororesin coated layer. The laminate of the present invention has high durability since a fluororesin is used, and particularly when a highly transparent fluororesin is used, the display color tone may be maintained over a long time. Further, the laminate of the present invention is also suitable as a protective plate of e.g. a device used outdoors, such as a solar cell, in view of light weight and high durability (light resistance and weather resistance).

### <Photoelectric Conversion Element>

The present invention further provides a photoelectric conversion element having the above laminate. Since the laminate of the present invention is excellent in the transparent and the durability, it is suitable as a substrate or a protective plate of a photoelectric conversion element. The photoelectric conversion element means both device which converts light energy into electric energy such as an organic thin film solar cell and device which converts electric energy to light energy such as an organic LED.

The laminate of the present invention is particularly suitably used as a substrate in view of the following properties. Since the laminate has high gas barrier properties by making use of properties of the glass sheet, in a photoelectric conversion element using an organic semiconductor material, deterioration (e.g. by oxygen and moisture) of the organic semiconductor material can be suppressed. By making use of the properties of the entire laminate, the substrate itself is excellent in the flexibility, and thus the flexibility of the photoelectric conversion element itself can be made high. Deterioration of the resin at high temperature is little by making use of the properties of the fluororesin, and thus the substrate can withstand a relatively high process temperature in preparation of the photoelectric conversion element. By making use of the properties of the fluororesin, the substrate is excellent in the durability (particularly the light resistance) and is less likely to undergo deterioration of the resin. Since the fluororesin coated layer is formed by coating, flatness of the laminate tends to be high. In a case where a resin film is bonded to a glass sheet, the laminate may not be flat in some cases due to roughness of the film, residual stress, etc. The influence is remarkable particularly when the glass sheet is thin. Whereas, in this case, due to a process of coating with a solution, not only the thickness is uniform but also influences of the resin on the glass sheet tend to be small, and the flatness of the laminate tends to be high. For example, if a laminate is placed on a flat metal mirror surface to observe interference fringes, optical interference may be observed due to undulations of the laminate in some cases, however, substantially no such interference is observed in the case of the laminate of the present invention.

### EXAMPLES

Now, the present invention will be described in further detail with reference to Examples, but the present invention is by no means restricted thereto.

### <Material>

### (Glass Sheet)

A glass sheet (10 cm×10 cm) of alkali-free glass (tradename: AN100) manufactured by Asahi Glass Company, Limited was used. The thickness was 50 μm or 100 μm.

### (Fluororesin Solution A1)

150 Parts by mass of a hydroxy group-containing fluororesin (tradename: LUMIFLON LF916F, manufactured by Asahi Glass Company, Limited, 100% flakes, number average molecular weight: 7,000, hydroxy value: 98 mgKOH/g, fluorine content: 25.6 mass %), 76 parts by mass of Sumidur N3300 (tradename, manufactured by Sumika Bayer Urethane Co., Ltd., polyisocyanate curing agent) and 1.5 parts by mass of dibutyltin dilaurylate were dissolved in 140 parts by mass of propylene glycol monomethyl ether acetate (PGMEA) to obtain fluororesin solution A1 (solid content: 62 mass %).

### (Fluororesin Solution A2)

Perfluorobutenyl vinyl ether (CF₂═CFOCF₂CF₂CF═CF₂) was subjected to cyclopolymerization using diisopropylperoxydicarbonate (((CH₃)₂CHOCOO)₂) as a polymerization initiator. The unstable terminal derived from the initiator was converted to —COF by heat treatment, which was hydrolyzed to be converted to —COOH thereby to obtain poly(perfluoro(butenyl vinyl ether)). The intrinsic viscosity [η] of the obtained polymer measured in a perfluoro(2-butyltetrahydrofuran) solution was 0.23. Further, the fluorine content was 68.3 mass %. The polymer was dissolved in perfluorotributylamine to obtain fluororesin solution A2 (solid content: 14 mass %).

### (Fluororesin Solution A3)

Polyvinylidene fluoride (KYNAR760 manufactured by Arkema, fluorine content: 59.4 mass %) was dissolved in N-methylpyrrolidone to obtain fluororesin solution A3 (solid content: 10 mass %).

### (Fluororesin Solution A4)

650 g of perfluorobiphenyl, 117 g of 1,3,5-trihydroxybenzene and 6,202 g of N,N-dimethylacetamide were put in a 10 L flask. 575 g of sodium carbonate was added at 60° C. with sufficient stirring. The mixture was held at 60° C. for 24 hours with stirring. The mixture was cooled to 0° C., 200 g of 4-acetoxystyrene and 532 g of potassium hydroxide were added, and the mixture was stirred at 0° C. for 24 hours. The obtained liquid was added dropwise to about 10 L of 0.5N aqueous hydrochloric acid to obtain precipitates. The obtained precipitates were washed and dried to obtain a white powder (fluorinated arylene ether polymer having vinyl groups as polymerizable functional groups, fluorine content: 35.9 mass %). The obtained curable fluororesin was dissolved in PGMEA to obtain fluororesin solution A4 (solid content: 15 mass %).

### (Fluororesin Solution A5)

500 g of deionized water, 125 g of tert-butyl vinyl ether, 2.5 g of ammonium perfluorooctanoate, 9.1 g of disodium hydrogenphosphate and 5.0 g of ammonium persulfate were put in a 1 L stainless steel autoclave. Oxygen in the system was removed, 126.5 g of tetrafluoroethylene was introduced, and the mixture was heated to 50° C. and reacted for 7.5 hours. The obtained solution was poured into methanol to obtain a polymer. The polymer was reacted with concentrated hydrochloric acid, washed and dried to obtain a tetrafluoroethylene/vinyl alcohol copolymer (fluorine content: 52.8 mass %). The copolymer was dissolved in a solvent mixture (a mixture of propylene glycol monomethyl ether (2 parts by mass) and isopropyl alcohol (1.5 parts by mass)) to obtain fluororesin solution A5 (solid content: 5 mass %).

### (Fluororesin Solution A6)

0.2 g of methyl silicate oligomer (MS51 manufactured by TAMA CHEMICALS CO., LTD.), 0.2 g of organo silica sol (manufactured by Nissan Chemical Industries, Ltd., 30 mass % isopropyl alcohol solution), 0.01 g of a titanate compound (manufactured by Shin-Etsu Chemical Co., Ltd., D-20) and 0.03 g of hexamethylcyclotrisilazane were mixed with 3.7 g of fluororesin solution A5 to obtain fluororesin (fluorine content: 48.8 mass %) solution A6 (solid content: 12%).

### (Hydrocarbon Resin Solution P1)

A methyl methacrylate polymer (manufactured by SIGMA-ALDRICH, weight average molecular weight: 120,000) was dissolved in PGMEA to obtain hydrocarbon resin solution P1 (solid content: 10 mass %).

### (Fluororesin Film P2)

A fluorinated ethylene propylene (FEP) film (film thickness: 25 μm) (tradename: NEOFLON NF-0025 manufactured by Daikin Industries, Ltd.) was used.

### (Hydrocarbon Resin Film P3)

A polyethylene terephthalate film (thickness: 50 μm) (tradename: COSMOSHINE A4100 manufactured by TOYOBO CO., LTD.) was used.

### <Method for Producing Laminate Sample>

In the following test, as a glass sheet, one having an adhesion-improving treatment (primer treatment) as the surface suitability-improving treatment applied to a side on which the resin was to be laminated was used. As the primer treatment, a silane coupling agent (tradename: KBM-903 manufactured by Shin-Etsu Silicone) was applied.

Fluororesin solution A1: The fluororesin solution A1 was applied to one side of the glass sheet by spin coating, and dried at 25° C. for 7 days for curing. The film thickness of the resin was 4 μm.

Fluororesin solution A2: The fluororesin solution A2 was applied to one side of the glass sheet by spin coating, and heated by a hot plate at 100° C. for 10 minutes and further in an oven at 100° C. for 1 hour and at 200° C. for 1 hour. The film thickness of the resin was 5 μm.

Fluororesin solution A3: The fluororesin solution A3 was applied to one side of the glass sheet by spin coating, and heated in an oven at 60° C. for 1 hour, and after the temperature was gradually increased and reached 200° C., at the temperature for 1 hour. The film thickness of the resin was 5 μm.

Fluororesin solution A4: The fluororesin solution A4 was applied to one side of the glass sheet by spin coating, and heated by a hot plate at 150° C. for 2 minutes and further in an oven at 150° C. for 10 minutes. The film thickness of the resin was 1 μm.

Fluororesin solution A5: The fluororesin solution A5 was applied to one side of the glass sheet by spin coating, and heated in an oven at 50° C. for 30 minutes, at 70° C. for 2 hours and at 100° C. for 1 hour. The film thickness of the resin was 5 μm.

Fluororesin solution A6: The fluororesin solution A6 was applied to one side of the glass sheet by spin coating, and heated in an oven at 50° C. for 30 minutes, at 70° C. for 2 hours and at 100° C. for 1 hour. The film thickness of the resin was 15 μm.

Hydrocarbon resin solution P1: The hydrocarbon resin solution P1 was applied to one side of the glass sheet by spin coating, and heated by a hot plate at 100° C. for 10 minutes and further in an oven at 100° C. for 1 hour and at 200° C. for 1 hour. The film thickness of the resin was 10 μm.

Fluororesin film P2: The fluororesin film P2 was pressure-bonded to the glass sheet at 200° C., followed by cooling to room temperature.

Hydrocarbon resin film P3: The hydrocarbon resin film P3 having a corona treatment applied thereto was pressure-bonded to the glass sheet at room temperature.

### <Evaluation>

### (Flexibility)

Opposing two sides of the laminate sample were held by both hands, and the flexibility was evaluated based on the following standards 0 (excellent): the laminate sample very easily bent; 0 (favorable): the laminate easily bent; and x (poor): the laminate hardly bent and broken if it was to be forcibly bent.

### (Flatness)

The laminate sample was gently placed on a polished metal mirror surface so that glass sheet faced the metal side and the resin faced the air side. The flatness was evaluated by visually observing interference fringes based on the following standards ◯ (favorable): substantially no fringes observed, and x (poor): fringes observed.

### (Transparency)

The transmitted light spectrum of the laminate sample within a range of from 400 to 700 nm was measured. ◯ (favorable): the lowest transmittance within a range of from 400 to 700 nm being at least 80%, and x (poor): the transmittance being less than 80%.

### (Initial Outer Appearance)

The outer appearance of the laminate sample was visually evaluated based on the following standards ◯ (favorable): no defects by foreign matters nor yellowing observed, and x (poor): at least one type of such drawbacks observed.

(Outer Appearance after Test)

The laminate sample was subjected to an accelerated weathering test using a metal weathering machine (manufactured by DAIPLA WINTES CO., LTD., tradename: METAL WEATHER). 17 Exposure cycles under the following conditions were regarded as exposure test corresponding to 100 hours, and the exposure test corresponding to 500 hours in total was carried out. The outer appearance after the exposure test was visually evaluated under the same evaluation standards as for the initial outer appearance.

Exposure Cycle:
Mode: L+D (L: irradiation, D: condensation in darkness)
   L: temperature 63° C., humidity 50%, 5 hours
   D: temperature 30° C., humidity 98%, 1 hour
REST mode: no condensation
Quantity of light: 50.0 mW/cm² (365 nm)
Shower: 10 seconds before and after D

TABLE 1

| | Glass sheet | | | | | Initial | Outer ap- |
|---|---|---|---|---|---|---|---|
| | thick- | | Flexi- | Flat- | Trans- | outer ap- | pearance |
| Ex. | ness/μm | Resin | bility | ness | parency | pearance | after test |
| 1 | 50 | A1 | ⊚ | ◯ | ◯ | ◯ | ◯ |
| 2 | 100 | A1 | ◯ | ◯ | ◯ | ◯ | ◯ |
| 3 | 50 | A2 | ⊚ | ◯ | ◯ | ◯ | ◯ |
| 4 | 100 | A2 | ◯ | ◯ | ◯ | ◯ | ◯ |
| 5 | 50 | A3 | ⊚ | ◯ | ◯ | ◯ | ◯ |
| 6 | 100 | A3 | ◯ | ◯ | ◯ | ◯ | ◯ |
| 7 | 50 | A4 | ⊚ | ◯ | ◯ | ◯ | ◯ |
| 8 | 100 | A4 | ◯ | ◯ | ◯ | ◯ | ◯ |
| 9 | 50 | A5 | ⊚ | ◯ | ◯ | ◯ | ◯ |
| 10 | 100 | A5 | ◯ | ◯ | ◯ | ◯ | ◯ |
| 11 | 50 | A6 | ⊚ | ◯ | ◯ | ◯ | ◯ |
| 12 | 100 | A6 | ◯ | ◯ | ◯ | ◯ | ◯ |
| 13 | 50 | P1 | ⊚ | ◯ | ◯ | ◯ | X |
| 14 | 100 | P1 | ◯ | ◯ | ◯ | ◯ | X |
| 15 | 50 | P2 | ⊚ | X | ◯ | ◯ | ◯ |
| 16 | 100 | P2 | ◯ | X | ◯ | ◯ | ◯ |
| 17 | 50 | P2 | ⊚ | X | ◯ | ◯ | X |
| 18 | 100 | P2 | ◯ | X | ◯ | ◯ | X |

### <Results>

The laminates of the present invention in Examples 1 to 12 are excellent in the flexibility and the transparency and are excellent in the flatness, and further they are excellent in the durability. Whereas, the laminates in Examples 13, 14, 17 and 18 are inferior in the durability. Further, the laminates in Examples 15 to 18 are inferior in the flatness. It is considered that when a resin film is laminated, it is difficult to uniformly apply a stress for lamination at the time of lamination, and further, the stress in the film tends to be non-uniform.

### (Slipping Property)

Each of the fluororesin solutions A2, A3 and A4 was applied to one side of an alkali-free glass sheet (AN-100 manufactured by Asahi Glass Company, Limited) (10 cm×10 cm×100 μm) by spin coating, and subjected to the heat treatment in the same manner as in Examples 4, 6 and 8 to obtain laminate samples having a fluororesin coated layer having a thickness of 2 μm in Examples 31 and 32 and a thickness of 5 μm in Example 33.

The friction was measured in accordance with JIS-K-7125: 1999 (ISO-8295: 1995). Specifically, an alkali-free glass sheet (AN-100 manufactured by Asahi Glass Company, Limited) (10 cm×10 cm×0.5 mm) was horizontally fixed on a test board. On the glass sheet, each laminate sample (10 cm×10 cm, glass sheet thickness: 100 μm) was placed so that the resin surface faced downward. A force gauge (SHIMPO FGP-5) was attached to the laminate sample. A petri dish of 50 mm in diameter was prepared and a weight was placed thereon so that the total weight would be 100 g. 10 Seconds after the petri dish was placed, it was horizontally pulled at 10 mm/sec, and the maximum pull strength (static friction) displayed on the force gauge was measured. As a Comparative Example, an alkali-free glass sheet (thickness: 100 μm) having no fluororesin coated layer formed thereon was used. The results are shown in Table 2.

The laminates of the present invention in Examples 31, 32 and 33 had favorable slipping properties with a small pull strength. They had favorable slipping properties even in comparison with Examples 35 in which the glass surfaces were contacted with each other. When a laminate has favorable slipping properties, in a case where a continuous long laminate is to be wound or cut sheets of the laminate are overlaid one on another, the desired overlaid state is likely to be achieved. That is, it is not necessary to forcibly arrange the laminates. Thus, it is possible to prevent the glass surface from being scared and broken.

Whereas, in Example 34 in which a non-fluororesin film was laminated, the pull strength was large. That is, when the film and the glass are overlaid, the slipping properties are low, and the glass surface tends to be scared and broken.

When a filler is incorporated in the resin coated layer to impart roughness to the resin surface, falling of the filler (solid particles) may occur in some cases. In such a case, the fallen filler may be attached to a transport apparatus or the like, thus leading to scars or breakage of the glass surface. In the laminate of the present invention, the fluororesin coated layer preferably contains no filler. In such an embodiment, contamination of a transport apparatus or the like by the fallen filler is likely to be prevented. Further, since the fluororesin coated layer is flat, microfabrication (for example, formation of an electronic circuit) may be applied to the glass surface or the fluororesin coated layer surface.

TABLE 2

| Ex. | Resin | Resin thickness/μm | Pull strength/N |
|---|---|---|---|
| 31 | A2 | 2 | 0.42 |
| 32 | A3 | 2 | 0.37 |
| 33 | A4 | 5 | 0.90 |
| 34 | P3 | 50 | 6.11 |
| 35 | — | — | 3.82 |

### (Electrostatic Chuck Handling Efficiency)

Each of the fluororesin solutions A2 and A3 was applied to one side of an alkali-free glass sheet (AN100 manufactured by Asahi Glass Company, Limited) (10 cm×10 cm×0.5 mm) by spin coating and subjected to heat treatment in the same manner as in Examples 4 and 6 to obtain laminate samples having a fluororesin coated layer having a thickness of 2 μm. Each laminate sample was placed on a horizontal stainless steel table so that the resin surface faced upward. An electrostatic chuck (manufactured by TOMOEGAWA CO., LTD., bipolar electrostatic chuck (150 mm 150 mm)) was pressed to the laminate sample under a pressing pressure of 5N, and lifted up while a predetermined voltage was applied. The applied voltage was 0.6 kV initially and was increased by 0.2 kV. The minimum applied voltage at which the laminate sample was properly chucked and stably lifted, was measured. As a Comparative Example, an alkali-free glass sheet (thickness: 500 μm) having no resin coated layer formed thereon was used. The results are shown in Table 3. The voltage being low indicates high workability by the electrostatic chuck. When the applied voltage is low, in a case where an electronic circuit is formed on the laminate, the risk of damaging the circuit will be low. With the laminates of the present invention in Examples 41 and 42, the minimum applied voltage was low, and the workability was high as compared with a glass sheet having no resin coated layer formed thereon.

TABLE 3

| Ex. | Resin | Minimum applied voltage/kV |
|---|---|---|
| 41 | A2 | 0.8 |
| 42 | A3 | 1.0 |
| 43 | — | 2.0 |

### <Photoelectric Conversion Element>

A photoelectric conversion element was prepared by using the laminate sample in Example 3. Specifically, an ITO (indium tin oxide) film was formed by sputtering on one side of a glass sheet having a thickness of 100 μm. The fluororesin solution A2 was applied to a side not coated with the ITO film by spin coating. Further, a buffering layer and an organic active layer were formed on the ITO film to form an aluminum electrode by vapor deposition. This laminate was subjected to an annealing treatment to obtain an organic thin film solar cell. The obtained organic thin film solar cell was flexible.

### INDUSTRIAL APPLICABILITY

According to the present invention, it is possible to provide a laminate which is light in weight and has high flexibility, which has favorable durability and which is optically useful. Such a laminate may be applied particularly to a protective plate and a photoelectric conversion element.

What is claimed is:

1. A glass sheet/fluororesin laminate comprising a glass sheet having a thickness of from 10 to 500 μm, and a fluororesin coated layer.

2. The glass sheet/fluororesin laminate according to claim 1, wherein the thickness of the fluororesin coated layer is from 0.1 to 1,000 μm.

3. The glass sheet/fluororesin laminate according to claim 1, wherein the thickness of the fluororesin coated layer is from 0.001 to 10 assuming that the thickness of the glass sheet is 1.

4. The glass sheet/fluororesin laminate according to claim 1, wherein the transmittance at a wavelength of from 400 to 700 nm is at least 80%.

5. The glass sheet/fluororesin laminate according to claim 1, wherein the fluororesin is a solvent-soluble fluororesin.

6. The glass sheet/fluororesin laminate according to claim 5, wherein the solvent-soluble fluororesin is a fluororesin having a cyclic structure in its main chain.

7. The glass sheet/fluororesin laminate according to claim 5, wherein the solvent-soluble fluororesin is polyvinylidene fluoride.

8. The glass sheet/fluororesin laminate according to claim 1, wherein the fluororesin is a cured fluororesin obtained by curing a solvent-soluble curable fluororesin.

9. A method for producing a glass sheet/fluororesin laminate, which comprises applying a solution of a fluororesin to at least one side of a glass sheet having a thickness of from 10 to 500 μm, and then removing the solvent to form a fluororesin coated layer.

10. The method for producing a glass sheet/fluororesin laminate according to claim 9, wherein the solution of a fluororesin is a solution of a curable fluororesin, and after the solvent is removed, the curable fluororesin is cured to form a coated layer of a cured fluororesin.

11. A protective plate comprising the glass sheet/fluororesin laminate as defined in claim 1.

12. A photoelectric conversion element, having the glass sheet/fluororesin laminate as defined in claim 1.

13. A semiconductor device having as a substrate the glass sheet/fluororesin laminate as defined in claim 1.
